(19) United States
(12) Patent Application Publication
(10) Pub. No.: US 2011/0199292 A1
(43) Pub. Date: Aug. 18, 2011

(54) Wrist-Mounted Gesture Device

(76) Inventor: Paul E. Kilbride, Rolling Meadows, IL (US)

(21) Appl. No.: 12/707,799

(22) Filed: Feb. 18, 2010

(51) Int. Cl. G09G 5/00; H03M 11/00

(52) U.S. Cl. 345/156; 341/20

(57) ABSTRACT

A wrist-mounted gesture device, system, and method is disclosed. The wrist-mounted gesture device includes at least one accelerometer adapted to detect acceleration caused by one or more gestures of the user. The accelerometer provides data to a microcontroller which is adapted to interpret the gesture data and match it with corresponding predefined gestures. The device includes wireless connection circuitry which allows the device to be wirelessly interfaced with an electronic device. The electronic device may be a device within the living space or environment of the user. A highly effective gesture system is ideally utilized in order to produce accurately recognizable gestures, in either one, two, or three dimensions. In certain embodiments, movements corresponding to movements toward and away from numbers in a standard keypad arrangement can be used, and vertical and horizontal movements corresponding to affirmative and negative gestures are used. In other embodiments, the device can be used in a mapping system of a room or interior space to assist users in finding objects or locations in such a room. In still other embodiments, the device can be used to assess tremors in a patient.

### BACKGROUND OF THE INVENTION

1. Field of the Invention

The present invention relates to a wrist-mounted gesture device, and more particularly, to a wrist-mounted gesture device for interfacing with the environment via detectable gestures.

2. Background

In modern societies, electronic devices abound in the environments and living spaces of people. People have a need to interact with these devices, whether they are communications equipment, televisions, audio systems, home appliances, etc. While conventional methods of providing input to such devices are numerous, including physical controls, remote, etc., there continues to be a need for more convenient ways to interact with such electronic devices.

In addition, those individuals having various disabilities or impairments may have difficulty interacting with various electronic devices in conventional fashions. For example, those having visual impairments or manual dexterity impairments may have difficulty operating conventional controls.

Accelerometers have been used increasingly in various electronics. For example, MEMS technology (microelectromechanical systems) has been used to detect motion. Some such systems have been used in gaming technology.

Hand and arm gestures have been used as a symbolic means of communication in various forms since prehistoric times. The use of various gestures and motions with the hands and arms is integrated into numerous cultures and communication styles. Thus, gestures are a natural and intuitive form of communicating information.

Various previous attempts have been made to make use of recognizing gestures in an automated fashion. For example, in U.S. Published Application No. 2008/10013826, a method of gesture recognition is disclosed. A set of cameras and sensors make use of reflected light to attempt to recognize a human gesture. Unfortunately, in order for such a system to be useful, the user must be positioned and remain in a specific location relative to the cameras.

U.S. Pat. No. 6,804,396, issued to Higaki et al., includes a gesture recognition system involving sound detection and image recognition. Such a system again involves specific location of a user, and requires a complicate set of technologies.

A hand held pointer device to control electronics is disclosed by U.S. Pat. No. 6,990,639, issued to Wilson. While this system enables a user to control an electronic device using a hand held point, the hands are encumbered, and natural gestures are not used.

Numerous other technologies have been employed for controlling electronic devices in various ways. However, an effective way to control such devices in a simple, hands-free and versatile manner has not been achieved. Thus, an effective gesture recognition system in which a user can make simple gestures without being encumbered would be advantageous.

### SUMMARY

The present invention is a wrist-mounted gesture device. The device is designed for hands-free mounting so that the user's hands remain free. It can be used to allow a user to interact with the user's environment through the use of gestures. In various embodiments, a user having a disability or impairment, such as a visual or manual dexterity impairment can benefit from use of the device.

The wrist-mounted gesture device includes an accelerometer, or a plurality of accelerometers, adapted to detect acceleration. The accelerometer detects movements of the user in the form of gestures. The accelerometer then sends gesture data to a microcontroller. The microcontroller is adapted, via programming, for example, to determine whether the gesture data matches a predefined gesture.

Wireless circuitry enables the device to be wirelessly interfaced with an electronic device. For example, the device may be wirelessly interfaced with an electronic device within the user's environment, such as a car, a computer, a television, a telephone, a kitchen appliance, or any other electronic device. Thus, the user is able to provide input to the electronic device wirelessly in order to control the electronic device via making a gesture with the hand or arm.

In various embodiments, the microcontroller accesses a database of gesture profiles to compare the gesture data received from the accelerometer to the profiles and determine whether there is a match. Various algorithms and models can be used to effectively match gesture data with gesture profiles.

Various gesture schemes are ideally used to enable users to accurately produce recognizable gestures, and to enable the microcontroller to accurately interpret the gesture data. For example, natural gestures can be used which correspond to natural responses a user might make, such as raising the hand toward the ear to answer a phone, or other motions which approximate the motion of a corresponding intended response.

Gesture movements can be made in either one, two, or three dimensions. In certain embodiments, a user may need to provide input to an electronic device in the form of a numerical response. Various gesture schemes can be used to facilitate numerical gestures. In a preferred embodiment, the layout of a standard keypad can be visualized in a two-dimensional plane. The user can make gestures from a center point toward the sides, top, bottom, and corners, and optionally then back again to a center point. In this fashion, a number which would be at the corresponding position on a keypad is indicated. A number in the center of the keypad can be indicating using a gesture orthogonal to the visualized plane of the keypad, and optionally back again. A zero can be indicated using motions opposite those of the center point number. The ease in making and recognizing such gestures can be used advantageously.

In embodiments in which a gesture such as a “yes” or “no” is desirable, a simple and easily reproduced and interpreted gesture system can be used. In one example, a simple up and down motion of the hand, wrist, or arm can be used to produce a “yes” response. Additionally, a side to side motion can be used to indicate a negative response. Such responses are natural responses corresponding to a typical yes or no nod. They are thus intuitive, but also easy to produce accurately and conducive to a high accuracy of proper interpretation.

In various other embodiments, an interior space mapping system can be implemented. The accelerometer system in the device can be used to track the real time location of the device, and thus, the user. A system, such as an auditory prompting system, can be used to guide an individual to various locations or objects within an interior space. This embodiment may be particularly beneficial to a user having a visual impairment or memory impairment.

In still other embodiments, the device can be used an assessment tool for hand and arm tremors. Patients suffering from such tremors can wear the device, which can track changes in the frequency, intensity, and duration of such tremors.

Still other objects and advantages of the present invention will become readily apparent to those skilled in the art from the following detailed description, wherein it is shown and described only the preferred embodiments of the invention, simply by way of illustration of the best mode contemplated of carrying out the invention. As will be realized, the invention is capable of other and different embodiments and its several details are capable of modifications in various obvious respects, without departing from the invention. Accordingly, the drawings, wherein like reference numerals represent like features, and description are to be regarded as illustrative in nature and not as restrictive.

### BRIEF DESCRIPTION OF THE DRAWINGS

FIG. 1 shows a perspective view of the wrist-mounted gesture device of the present invention.

FIG. 2 shows an interface diagram of the wrist-mounted gesture device of the present invention.

FIG. 3 shows a chart indicating one possible scheme of gestures according to the present invention.

FIG. 4 shows a standard keypad gesture scheme according to certain embodiments of the present invention.

FIG. 5 shows other possible gesture schemes according to the present invention.

FIG. 6 shows one possible model for accomplish recognition of gesture data according to the present invention.

FIG. 7 shows a graphic output representation of data as would be collected from a tremor assessment.

### DETAILED DESCRIPTION OF THE INVENTION

While this invention is susceptible of embodiments in many different forms, there are shown in the drawings and will herein be described in detail, preferred embodiments of the invention with the understanding that the present disclosure is to be considered as an exemplification of the principles of the invention and is not intended to limit the broad aspect of the invention to the embodiments illustrated.

The present invention is a wrist-mounted gesture device 10. The wrist mounted gesture device 10 includes one or more accelerometers 15 adapted to detect acceleration caused by one or more gestures of a user. Accelerometers 15 suitable for the present invention are preferably situated to detect motion in one, two, or three dimensions. Accelerometers 15 are preferably MEMS accelerometers; however, any suitable accelerometer or accelerometer configuration is contemplated within the scope of the present invention. Additionally, or in place of, one or more MEMS gyroscopes may be used for accelerometers 15. The device is preferably design to be a rugged system. It may be damage resistant, and it may be water-resistant.

The accelerometer 15 provides gesture data to a microcontroller 20. The microcontroller 20 may be a system on a chip having interface circuitry with the accelerometer 15. The microcontroller 20 is adapted or programmed, via software or hardware, to receive gesture data generated by the accelerometer 15 and determine whether the gesture data matches a predefined gesture.

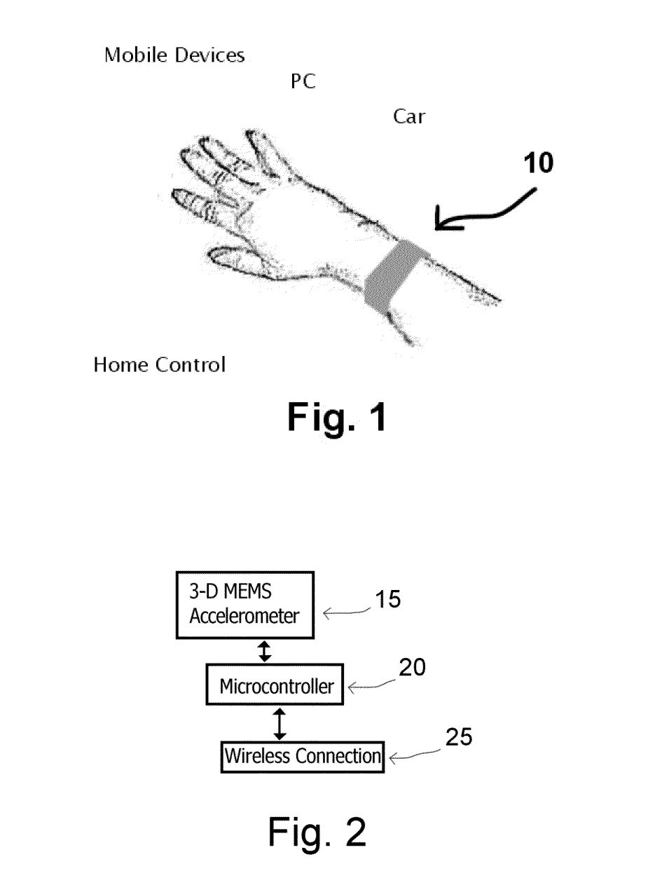

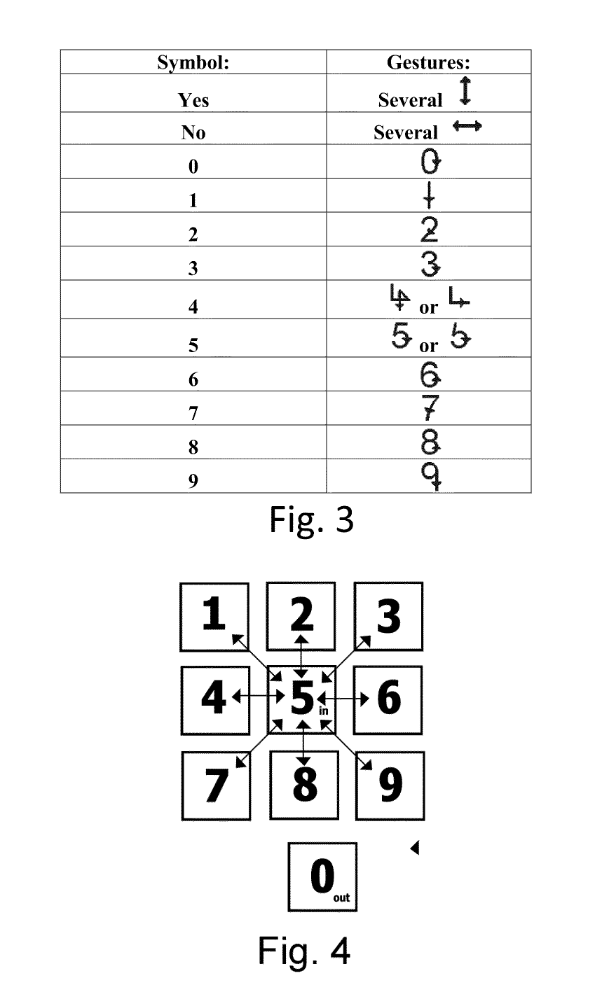

The gesture device of the present invention also includes wireless connection circuitry 25 enabling the device 10 to be wirelessly interfaced with one or more electronic devices, as shown pictorially in FIG. 1. The wireless connection circuitry 25 can be any suitable protocol or system. In various embodiments, the wireless connection circuitry may be Bluetooth, Zigbee, WiMax, WiFi, or any other suitable wireless protocol or system. The wireless connection 25 preferably interfaces with an electronic device within the environment of the user.

In various embodiments, the microcontroller 20 determines whether gesture data matches a gesture profile by accessing a database of gesture profiles and comparing the gesture data with the profiles. Any of numerous algorithms or systems can be used to enable the microcontroller to determine whether gesture data matches a gesture profile. The data may be broken into subcomponents, such as direction and speed data, which may be compared with templates of existing gesture data.

In certain preferred embodiments, a system known as a Hidden Markov Model (“HMM”) can be used to recognize gestures. The gesture data can be broken into sequential symbols. The HMM is a mathematical model which describes a complex system in terms of a finite set of possible system states, with statistical information representing the probability of each possible transition from one state to another. Thus, using an HMM system, the microcontroller can break the gesture data down into subparts and compare them with gesture profile information to determine a probability of a match.

The wrist-mounted gesture device 10 of the present invention is used to interface with various possible electronic devices within the environment or living space of the user. It is not used or intended as a gaming device, but rather, a convenience in interfacing with electronic devices, or, in various preferred embodiments, as an aid to users having any type of disability or impairment which might make it difficult to control such electronic devices in a conventional manner. Electronic devices controlled by the gesture device 10 may include computers, telephones, other communications equipment, mobile devices, appliances, automobiles, home devices, or any other suitable device which can be controlled by a user. The user provides input to such devices through the use of gestures. Having the device mounted to the wrist enables the user to keep the user's hands free. Ideally, various electronic devices or functions or controls of electronic devices can be operated through input from the user's gestures without the need for the user to press any buttons or operate any controls directly on the device 10 aside from moving the device in the appropriate gesture motions. Natural gestures, such as those which include motions which are related in some way to the corresponding functionality, are used to create an intuitive system. For example, the answering of a telephone may include a gesture in which the hand or wrist is raised toward the user's ear. Other natural gestures might include a substantially vertical up and down motion to indicate an affirmative response akin to a “yes” nod of the head, or a horizontal back and forth (side to side) motion for a negative response akin to a “no” shake.

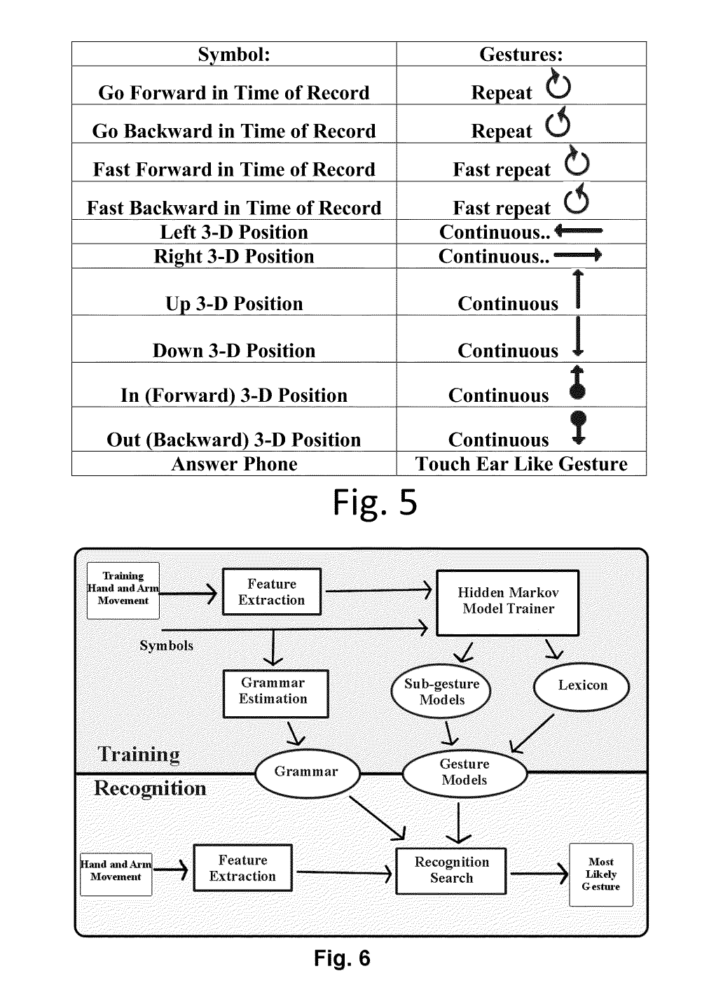

In certain embodiments, an electronic device may require a numerical input. For example, the dialing of a phone, or other numerical input needs, can be accomplished using the device 10 with a suitable gesture system. One such gesture system for numerical input is shown in FIG. 5. Another preferred system for numerical gestures is shown in FIG. 4. This system can be particular suitable as a natural way for a user to create numerical gestures, and is effective in that it has a high interpretation accuracy rate. A user creates these gestures with reference to a standard keypad configuration in a two-dimensional plane.

In the keypad gesture scheme, such as that shown in FIG. 4, the user preferably moves his hand, wrist, or arm, from a center point out toward the layout location of the number to be indicated. Preferably, the gesture also includes a returning to the center point position. Thus, in the layout shown, the user would move from the central position toward and away from the center “5” position, and toward any of the 1, 2, 3, 4, 6, 7, 8, and 9 positions, and then, preferably, back toward the 5 position, to indicate those numbers, respectively. Such a system is natural and easy for the user to learn and produce accurately in a way that the microcontroller has a high probability of correctly recognizing the gesture. The 5 and 0 gestures can include a motion in and out, or out and in of the 2-dimensional layout plane, preferably substantially along an orthogonal to that plane. Tests have shown that gestures in this fashion can be produced and recognized with a high degree of accuracy in test subjects.

In various other embodiments, the wrist-mounted gesture device 10 may interface with an electronic device which can provide location information and feedback to the user. The location of the gesture device 10 can be detected or tracked, for example, via the accelerometer activity of the device 10. Such a system can be of great assistance to individuals who may have a disability or impairment which makes it difficult to navigate or find objects in an interior space. For example, an individual having a visual impairment or memory impairment may benefit from the system helping them find locations or objects within the space. The interior space may be a kitchen, a plurality of rooms of a living space, a working space, or any other interior space. The feedback can include information which indicates to the user the directions needed to find the location or object of interest. While it may be most convenient to use a wrist mounted device in this embodiment, it may also be possible to make use of a device which is hand held or carried or worn in another fashion. A wand, remote, or other embodiment of the device may be used.

In yet other embodiments of the invention, the device 10 is used as a tremor assessment tool. In this embodiment, such a device is either hand or wrist mounted, hand held, or otherwise mounted or worn near or on the hand. The device again includes an accelerometer or accelerometer configuration in operative relation with a microcontroller. Data from a subject using the device is received by an assessment tool, and sequences of data from the device are tracked and interpreted to assess hand tremor activity and changes.

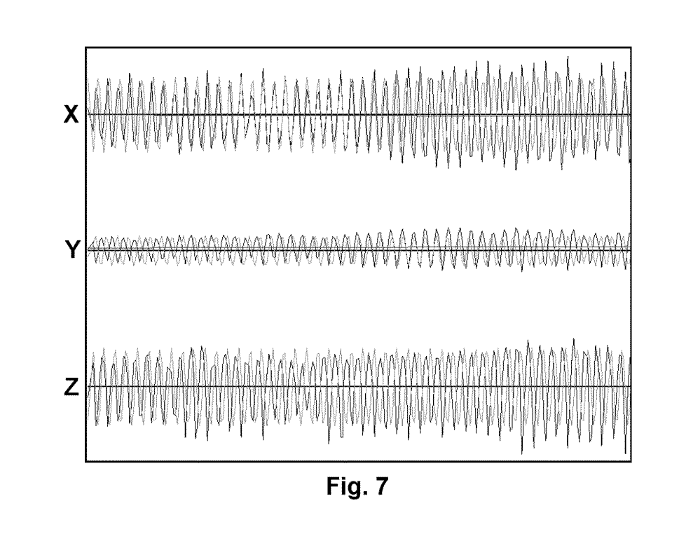

Hand tremor activity can be tracked and assessed in one, two, or three dimensional space. A battery of tests can be administered, which may include having the subject attempt to hold a hand steady for a period of time, and for several such periods of time. Data is generated, such as that shown in FIG. 7. The three rows of tremor displacement data over time may be separated X, Y, and Z axis data, respectively.

While specific embodiments have been illustrated and described, numerous modifications come to mind without significantly departing from the spirit of the invention and the scope of protection is limited by the scope of the accompanying claims.

What is claimed is:

1. A wrist-mounted gesture device comprising:
at least one accelerometer adapted to detect acceleration caused by one or more gestures of a user,
a microcontroller interfaced with said accelerometer for receiving gesture data from said accelerometer and adapted to determine whether the gesture data matches a pre-defined gesture,
wireless connection circuitry enabling said device to be wirelessly interfaced with an electronic device.

2. The wrist-mounted gesture device according to claim 1, wherein said microcontroller is adapted to access a database of gesture profiles and compare said gesture data with profiles in said database of gesture profiles to determine whether said gesture data matches one of said gesture profiles.

3. The wrist-mounted gesture device according to claim 1, wherein said microcontroller is programmed to use a Hidden Markov Model to analyze said gesture data.

4. The wrist-mounted gesture device according to claim 1, wherein said electronic device is a non-gaming device.

5. The wrist -mounted gesture device according to claim 1, wherein said device provides input to said electronic device, which input corresponds with said gesture data.

6. The wrist-mounted gesture device according to claim 5, wherein said microcontroller recognizes gestures which correspond with numbers.

7. The wrist-mounted gesture device according to claim 6, wherein said gestures which correspond with numbers comprise motions in a two-dimensional plane.

8. The wrist -mounted gesture device according to claim 7, wherein said gestures which correspond with numbers comprise gestures which correspond to the layout of a standard keypad.

9. The wrist-mounted gesture device according to claim 8, wherein the layout of the standard keypad comprises a location of numbers 1, 2, and 3 in a top row consecutively from left to right, numbers 4, 5, and 6 in a middle row consecutively from left to right, and numbers 7, 8, and 9 in a bottom row consecutively from left to right, and wherein said gestures which correspond with numbers comprise movements between a middle position on said keypad layout toward a desired number.

10. The wrist-mounted gesture device according to claim 9, wherein said gestures which correspond with numbers further comprise movements between a middle position on said keypad layout toward a desired number from said middle position toward said desired number and then back to said middle position.

11. The wrist-mounted gesture device according to claim 10, wherein said middle position corresponds to a layout location for the number 5, and wherein a gesture for the number 5 comprises a movement substantially perpendicular to said 2-dimensional plane.

12. The wrist-mounted gesture device according to claim 11, wherein a gesture for the number 0 comprises a movement substantially perpendicular to said 2-dimensional plane distinct from said gesture for the number 5.

13. The wrist -mounted gesture device according to claim 11, wherein said electronic device is a phone.

14. The wrist-mounted gesture device according to claim 11, wherein said electronic device is communications equipment.

15. The wrist-mounted gesture device according to claim 1, wherein said electronic device accesses mapping data, and wherein said electronic device provides feedback to a user corresponding to a location of said gesture device.

16. The wrist-mounted gesture device according to claim 15, wherein said feedback comprises information for directing a user to a desired location.

17. The wrist -mounted gesture device according to claim 16, wherein said mapping data comprises mapping data corresponding to the layout of an interior of a room.

18. The wrist-mounted gesture device according to claim 5, wherein said gestures comprise movements which correspond to natural movements associated with a desired function.

19. The wrist -mounted gesture device according to claim 18, wherein said function comprises answering a phone, and wherein said natural movements comprise lifting a user's hand toward a user's ear.

20. The wrist-mounted gesture device according to claim 5, wherein said microcontroller recognizes gestures which correspond with an affirmative gesture, and wherein said affirmative gesture comprises a substantially vertical movement of the wrist.

21. The wrist-mounted gesture device according to claim 5, wherein said microcontroller recognizes gestures which correspond with a negative gesture, and wherein said negative gesture comprises a substantially horizontal movement of the wrist.

22. The wrist-mounted gesture device according to claim 5, wherein said microcontroller recognizes gestures which correspond to movements in a two-dimensional plane.

23. The wrist-mounted gesture device according to claim 5, wherein said microcontroller recognizes gestures which correspond to movements in a three-dimensional space.

24. The wrist-mounted gesture device according to claim 5, wherein said electronic device comprises a device disposed in a living space of a user.

25. A method for assessing hand tremor comprising the steps of:
receiving data from a hand held or hand mounted or wrist mounted gesture device having an accelerometer therein and a microcontroller operatively interfaced with said accelerometer via an electronic assessment tool, and
tracking sequences of said data and interpreting said data to correspond with hand tremor activity.
